(19) United States
(12) Patent Application Publication
(10) Pub. No.: US 2010/0289068 A1
(43) Pub. Date: Nov. 18, 2010

(54) Thin Film Transistor Structure

(75) Inventors: Yi-Chang Yang, Hsinchu (TW); Hsiu-Ju Lin, Hsinchu (TW); Hsiao-Wei Cheng, Hsinchu (TW)

Correspondence Address: THOMAS, KAYDEN, HORSTEMEYER & RISLEY, LLP, 600 GALLERIA PARKWAY, S.E., STE 1500, ATLANTA, GA, 30339-5994, US

(73) Assignee: AU OPTRONICS CORP., Hsinchu (TW)

(21) Appl. No.: 12/535,871

(22) Filed: Aug. 5, 2009

(30) Foreign Application Priority Data
May 12, 2009 (TW) 98115664

(51) Int. Cl. H01L 29/786

(52) U.S. Cl. 257/288; 257/72; 257/59; 257/347; 257/E29.273; 257/E29.299

(57) ABSTRACT

A thin film transistor structure is provided. The thin film transistor structure includes a source and a drain. The corresponding opposite surfaces of the source and the drain are at least partially complementary and continuous convex-concave surfaces so that the charging ability of the thin film transistor would be increased due to an extending length of the continuous convex-concave surfaces.

This application claims priority to Taiwan Patent Application No. 098115664 filed on May 12, 2009, the disclosures of which are incorporated herein by reference in their entirety.

### CROSS-REFERENCES TO RELATED APPLICATIONS

Not applicable.

### BACKGROUND OF THE INVENTION

1. Field of the Invention

The present invention relates to a thin film transistor, and more particularly, to a thin film transistor structure.

2. Descriptions of the Related Art

With the advancement of science and technology, various electronic products equipped with displays have become indispensable to modern daily life. Thin film transistor liquid crystal displays (TFT LCDs), which save power, are free of radiation, have a small volume and consume little power, have gradually replaced traditional cathode ray tube (CRT) displays and have been widely applied in display panels of various electronic products.

Active matrix liquid crystal displays (LCDs) are mainstream products in the current LCD market. The working principle of an active matrix LCD is briefed as follows: light is emitted by a backlight source and then passes through a polarizer to the liquid crystal molecules, light changes its polarizing angle depending on the alignment of liquid crystal molecules and then the transmitted light is guided through a color filter and another polarizer. In this way, the alignment of the liquid crystal molecules can be adjusted by using thin film transistors to alter the voltage, thereby producing light rays of different intensities and colors to present different pictures on the LCD panel.

As the demand of the LCD size has increased over recent years, relevant techniques have been developed accordingly. To adapt to the bigger LCD size, the number of pixels, which is the basic unit of image display, has also increased. On the other hand, since the number of thin film transistors is proportional to that of pixels, the number of thin film transistors also increases accordingly. However, as the previous paragraph has described, an important factor that dominates the reaction time for the LCD to display images is the electric reaction speed of the thin film transistors. Therefore, to control the electric reaction speed of a large number of thin film transistors, the reaction time must be relatively long for a large-size LCD to display an image. In this case, many methods for improving the thin film transistors' ability of charging the pixels are proposed to maintain or increase the image refresh frequency of large-size LCDs.

FIG. 1A illustrates a conventional thin film transistor 1 that comprises a source 11, a drain 12 and a gate (not shown). The source 11 and the drain 12 define an extending length 13 (known as the channel width W in the art) and a distance 14 (known as the channel length L in the art) therebetween. As the current for charging the pixels by the thin film transistor 1 is proportional to a ratio of the extending length 13 to the distance 14 (known as the W/L ratio in the art), one of the methods for improving the charging ability of the thin film transistor 1 is to increase the W/L ratio. As shown in FIG. 1A, a symmetric structure is adopted for the source 11 and the drain 12. Therefore, to increase the W/L ratio, what must be done is to increase the extending length 13 or reduce the distance 14. However, the reduction in the distance 14 is limited, that is, the distance 14 shall not be zero theoretically, and so increasing the extending length 13 becomes a preferable option to increasing the W/L ratio. However, the maximum length to which the extending length 13 can be increased is also limited because the size of the thin film transistor 1 must match that of the pixel. Accordingly, to overcome the limitations suffered by the aforesaid symmetric structure, an asymmetric one is developed.

In reference to FIG. 1B, the asymmetric thin film transistor 1′ comprises, as its basic structure, a rectangular source 11′, a U-shaped drain 12′ and a gate (not shown), wherein the source 11′ and the drain 12′ can be replaced by each other as a drain and a source. The source 11′ is disposed in a U-shaped opening of the drain 12′, with an extending length 13′ and a distance 14′ being defined therebetween. If the distance 14′ in the asymmetric thin film transistor 1′ equals the distance 14 in the symmetric thin film transistor 1, the extending length 13′ is greater than the extending length 13. In this way, the W/L ratio can be increased effectively with minimum change in the overall size of the thin film transistor, thereby enhancing the charging ability thereof.

Though the aforesaid asymmetric structure or its combination can increase the W/L ratio thereof, it still has many disadvantages to be overcome. One of the disadvantages is that the overall size of the thin film transistor increases with the complexity of the asymmetric structure, which is unfavorable for arranging the thin film transistor in the LCD. Furthermore, as the thin film transistor increases in size, the accompanying parasitic capacitor thereof also increases inevitably. This leads to more space occupation and an unnecessary consumption of energy.

In view of this, to meet the power supply requirement of the large-size LCDs, it is a highly desirable topic in the art to improve the charging ability of the thin film transistor based on the existing symmetric and asymmetric structures without increasing the size of the transistor.

### SUMMARY OF THE INVENTION

To solve the above problems, the primary objective of the present invention is to provide a thin film transistor structure, which has a similar size but a longer extending length compared with the existing thin film transistor structure. Therefore, the ratio of the extending length to the distance is increased and the charging current from the thin film transistor to the pixels becomes greater, which greatly improves the charging ability of the thin film transistor.

To this end, the present invention provides a thin film transistor structure, which comprises a source and a drain. The source comprises a first portion with a first edge, and the drain comprises a second portion with a second edge. The first edge faces towards the second portion, the second edge faces towards the first portion, and the first edge and second edge have a plurality of convex-concave surfaces respectively, with the convex-concave surfaces of the first edge and the convex-concave surfaces of the second edge being substantially complementary. The first portion and the second portion define an extending length along the convex-concave surfaces, and the first edge and the second edge define a distance therebetween.

The present invention further provides a thin film transistor structure, which comprises a source and a drain. The source comprises a first main structure and a first microstructure, wherein the first microstructure is at least partially formed along the contour of the first main structure; the drain comprises a second main structure and a second microstructure, wherein the second microstructure is at least partially formed along the contour of the second main structure. The first microstructure at least partially faces towards the drain, the second microstructure at least partially faces towards the source, the first microstructure and the second microstructure have a plurality of convex-concave surfaces respectively, and the convex-concave surfaces of the first microstructure and the convex-concave surfaces of the second microstructure correspond to each other. The first main structure and the second main structure operatively define an extending length along the convex-concave surfaces, while the first microstructure and the second microstructure define a distance therebetween.

Compared with the planar surface between the source and the drain in the conventional thin film transistor, a plurality of complementary convex-concave surfaces are formed as the opposite surfaces between the source and the drain in the present invention. In this way, the extending length is substantially prolonged with the distance still remaining unchanged. Thus, the ratio of the extending length to the distance is increased, and the charging ability of the thin film transistor gets improved. Furthermore, the thin film transistor structure of the present invention can be widely used in the existing symmetric and asymmetric structures without varying the size thereof, thus avoiding the problem of increased parasitic capacitor due to the increased size.

The detailed technology and preferred embodiments implemented for the subject invention are described in the following paragraphs accompanying the appended drawings for people skilled in this field to well appreciate the features of the claimed invention.

### BRIEF DESCRIPTION OF THE DRAWINGS

FIG. 1A is a schematic view of a conventional thin film transistor with a symmetric structure;

FIG. 1B is a schematic view of a conventional thin film transistor with an asymmetric structure;

FIG. 2A is a schematic view of a symmetric thin film transistor structure according to the first embodiment of the present invention;

FIG. 2B is a schematic view of another example of the symmetric thin film transistor structure according to the first embodiment of the present invention;

FIG. 2C is a schematic view of a further example of the symmetric thin film transistor structure according to the first embodiment of the present invention;

FIG. 3A is a schematic view of an asymmetric thin film transistor structure according to the second embodiment of the present invention;

FIG. 3B is a schematic view of another example of the asymmetric thin film transistor structure according to the second embodiment of the present invention;

FIG. 3C is a schematic view of a further example of the asymmetric thin film transistor structure according to the second embodiment of the present invention;

FIG. 4 is a schematic view of a combined asymmetric thin film transistor structure according to the third embodiment of the present invention; and

FIG. 5 is a schematic view of a whirl-shaped asymmetric thin film transistor structure according to the fourth embodiment of the present invention.

### DESCRIPTION OF THE PREFERRED EMBODIMENT

In the following descriptions, the embodiments will be described to illustrate a thin film transistor structure of the present invention which comprises a source and a drain. It should be noted that these embodiments are provided herein only for illustrative purposed but not to limit the present invention and other embodiments will be readily known by those skilled in the art upon reviewing the disclosures of the present invention.

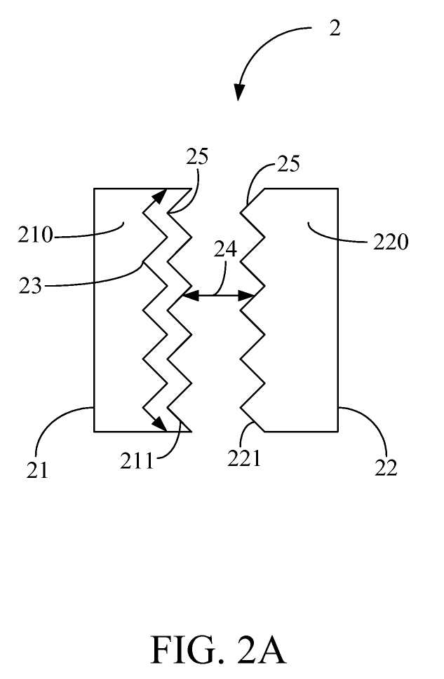

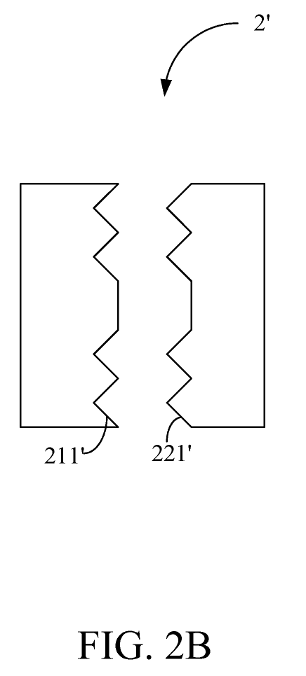

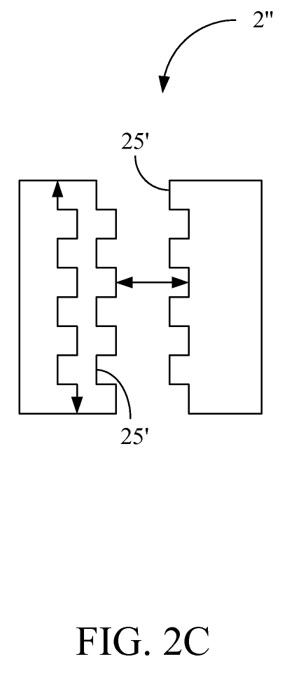

The first embodiment of the present invention is a symmetric thin film transistor structure 2 as shown in FIG. 2A. The thin film transistor structure 2 comprises a source 21, a drain 22, a gate (not shown) insulated from the source 21 and the drain 22, and a channel layer (not shown) having two ends substantially electrically connected to the source 21 and the drain 22 respectively. The source 21 and the drain 22 may also be replaced by each other as a drain and a source. The source 21 comprises a first portion 210 with a first edge 211, and the drain 22 comprises a second portion 220 with a second edge 221. The first edge 211 faces towards the second portion 220, the second edge 221 is toward the first portion 210, and the first portion 210 is substantially parallel to the second portion 220. Specifically, the first edge 211 and the second edge 221 have a plurality of continuous convex-concave surfaces 25 respectively. The convex-concave surfaces 25 of the first edge 211 and the convex-concave surfaces 25 of the second edge 221 are substantially complementary. An extending length 23 is defined along the convex-concave surfaces 25, and a distance 24 is defined between the first edge and the second edge.

In another example of the present invention, as shown in FIG. 2B, the thin film transistor structure 2′ is different from the thin film transistor structure 2 in that the first edge 211′ and the second edge 221′ of the thin film transistor structure 2′ have a plurality of partially continuous convex-concave surfaces. Specifically, the first edge 211′ and the second edge 221′ combine the planar surface and parts of the first edge 211 and the second edge 221. It should be particularly noted that this example is provided only to illustrate that the partially continuous convex-concave surfaces may also accomplish the purpose of the present invention, but not to limit the positions where these partially continuous convex-concave surfaces are formed. In yet another example, the two ends of the U-shaped drain of the asymmetric thin film transistor structure act as the second portion, and a plurality of convex-concave surfaces are formed on the two ends to form discontinuous convex-concave surfaces. That is, these convex-concave surfaces are at least partially continuous.

In reference again to FIG. 2A, in this embodiment, the convex-concave surfaces 25 are a plurality of sharp angles of 120 degrees (not exactly drawn to scale in the figure). In other words, the first edge 211 and the second edge 221 have a plurality of sharp angles of 120 degrees which are complementarily engaged with each other. In other examples, the sharp angles can be other degrees and, preferably, between about 60 and 120 degrees.

The thin film transistor structure of this embodiment may also be implemented as other examples. For example, the convex-concave surfaces of the thin film transistor structure 2″ are a plurality of rectangles 25′ as shown in FIG. 2C. In other words, provided that the first edge and the second edge can engage with each other complementarily without needing to change the sizes of the source and drain, the convex-concave surfaces may be of other shapes (e.g., a rectangle, an arc, a trapezoid, or any multi-lateral shape, and in the case of an arc, the central angle thereof should preferably range about 60 to 120 degrees, although the present invention is not merely limited thereto) or a combination thereof, which can be readily appreciated by those skilled in the art and thus will not be further described herein.

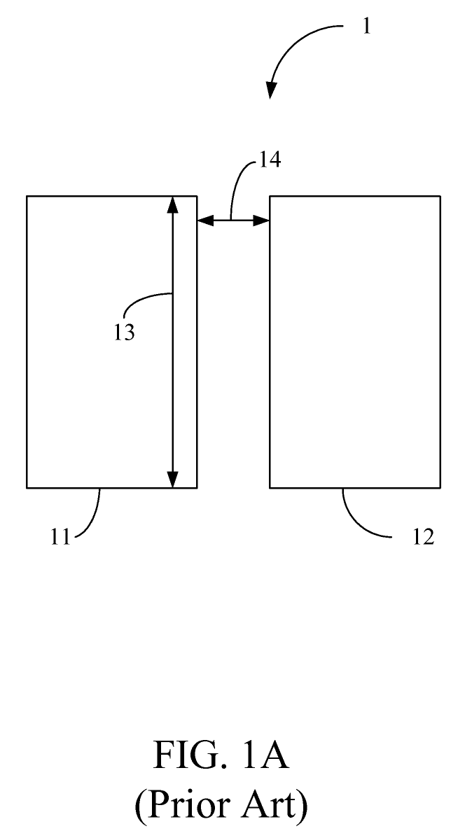

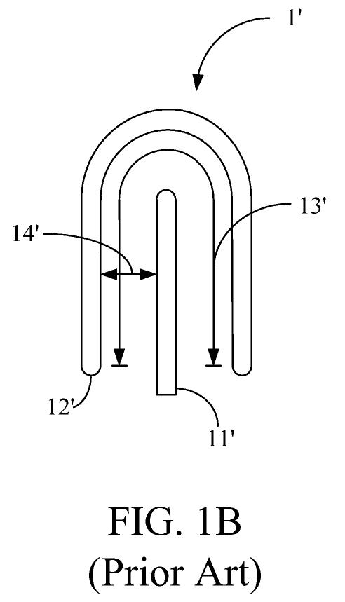

As compared with the prior art of FIG. 1A, when the distance 24 and the distance 14 are adjusted to the same value, the extending length 23 is twice of the extending length 13. Therefore, the ratio of the extending length 23 to the distance 24 is twice the ratio of the extending length 13 to the distance 14, so the charging ability is substantially doubled. It should be further noted that the ratio of the extending length 23 and the distance 24 is substantially between 1 and 20 for balance between the desired charging ability and the size limitations in process. Furthermore, as compared with the prior art, this embodiment changes the portions of the thin film transistor into angular shapes with the same volume, so the charging ability of this embodiment can be improved without increasing the parasitic capacitor.

In addition, the thin film transistor structure according to the first embodiment of the present invention may also be implemented into various existing asymmetric structures; for example, the source has a male structure while the drain has a female structure. The application of the present invention in the asymmetric structures will be further described in the following embodiments.

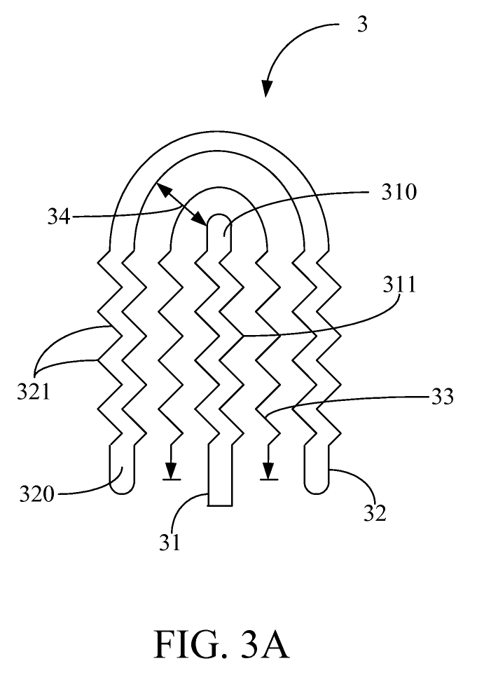

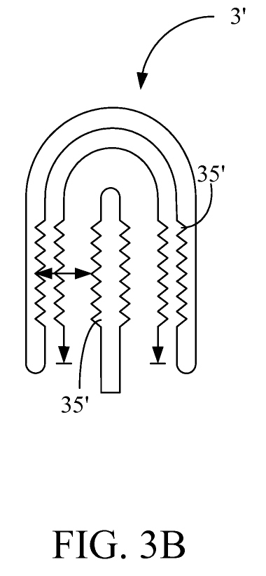

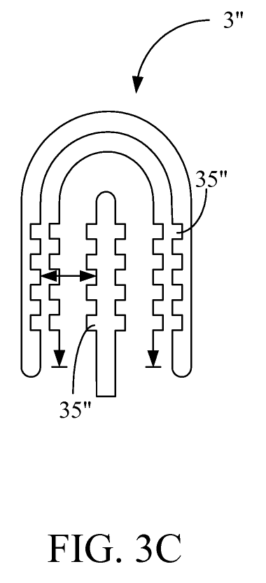

The second embodiment of the present invention is an asymmetric thin film transistor structure 3, as shown in FIG. 3A. The thin film transistor structure 3 comprises a source 31, a drain 32, a gate (not shown) insulated from the source 31 and the drain 32, and a channel layer (not shown) with two ends substantially electrically connected to the source 31 and the drain 32 respectively, wherein the source 31 and the drain 32 can be replaced by each other as a drain and a source. The source 31 comprises a first main structure 310 and a first microstructure 311, with the first microstructure 311 being at least partially formed along the contour of the first main structure 310. The drain 32 comprises a second main structure 320 and a second microstructure 321, with the second microstructure 321 being at least partially formed along the contour of the second main structure 320. The first microstructure 311 at least partially faces towards the drain 32, while the second microstructure 321 at least partially faces towards the source 31. The first main structure 310 of the source 31 is rectangular, and the second main structure 320 of the drain 32 is U-shaped. The U-shaped drain 32 is substantially adapted to encircle the rectangular source 31. The first microstructure 311 and the second microstructure 321 have a plurality of continuous convex-concave surfaces respectively, and the convex-concave surfaces of the first microstructure 311 and the convex-concave surfaces of the second microstructure 321 are substantially complementary. The first main structure 310 and the second main structure 320 are adapted to define an extending length 33 respectively along the convex-concave surfaces, and the first microstructure 311 and the second microstructure 321 define a distance 34 therebetween.

In this embodiment, each of the plurality of convex-concave surfaces has an angular shape with a sharp angle of about 120 degrees (not exactly shown to scale). More specifically, the second microstructure 321 is formed partially on both sides of the two ends of the U-shape of the drain 32 and has a plurality of sharp angles of about 120 degrees; the first microstructure 311 is partially formed on both sides of the rectangle of the source 31 according to the distribution of the second microstructure 321 and also has a plurality of sharp angles of about 120 degrees. Furthermore, the angular convex-concave surfaces comprise at least a concave and a convex, in which the angular concaves of the first microstructure 311 correspond to the convexes of the second microstructure 321 and the angular convexes of the first microstructure 311 correspond to the angular concaves of the second microstructure 321. It should be appreciated that the sharp angles may also be of different degrees which preferably range about 60 to 120 degrees in other examples.

The thin film transistor structure of this embodiment may also be implemented as other examples. For example, the convex-concave surfaces 35′ of the second microstructure 321 may be only partially formed on a single side of the two ends of the U-shape of the drain 32 as shown in FIG. 3B. Similarly, these convex-concave surfaces may also be a plurality of rectangles 35″ formed on both sides of the two ends of the U-shape of the drain 32, as shown in FIG. 3C. That is, provided that the first microstructure 311 and the second microstructure 321 can engage with each other complementarily, the plurality of convex-concave surfaces may be of other shapes (e.g., a rectangle, an arc, a trapezoid, or any multi-lateral shape, and in the case of an arc, the central angle thereof preferably ranges about 60 to 120 degrees, although the present invention is not merely limited thereto) or a combination thereof, which can be readily appreciated by those skilled in the art and thus will not be further described herein.

As compared with the prior art of FIG. 1B, when the distance 34 and the distance 14 are adjusted to the same value, the extending length 33 becomes significantly greater than the extending length 13. Therefore, the ratio of the extending length 33 to the distance 34 increases accordingly, resulting in the improvement of the charging ability of the thin film transistor structure 3. It should be further noted that the ratio of the extending length 33 to the distance 34 is substantially between 1 and 20 for balance between the preferable charging ability and the size limitations in the process. Likewise, as compared with the prior art, this embodiment changes portions of the thin film transistor into angular shapes with the same volume, so the total volume of the thin film transistor remains unchanged and the charging ability of this embodiment can be improved without increasing the parasitic capacitor.

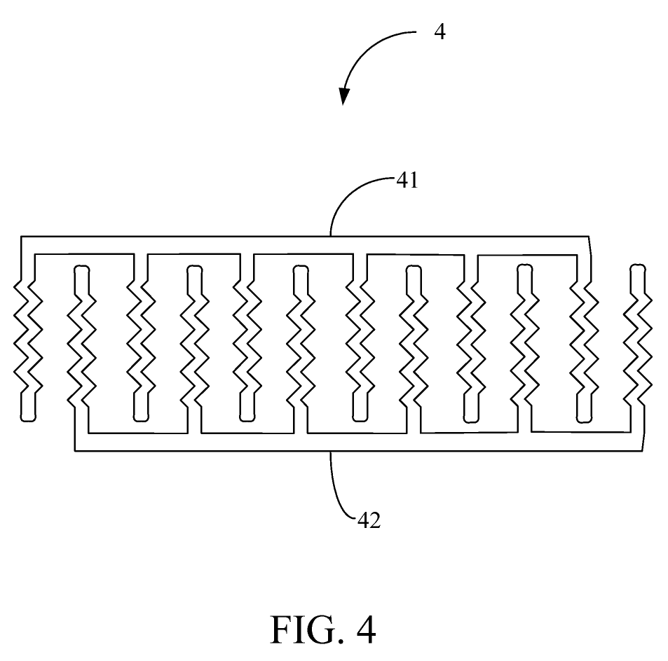

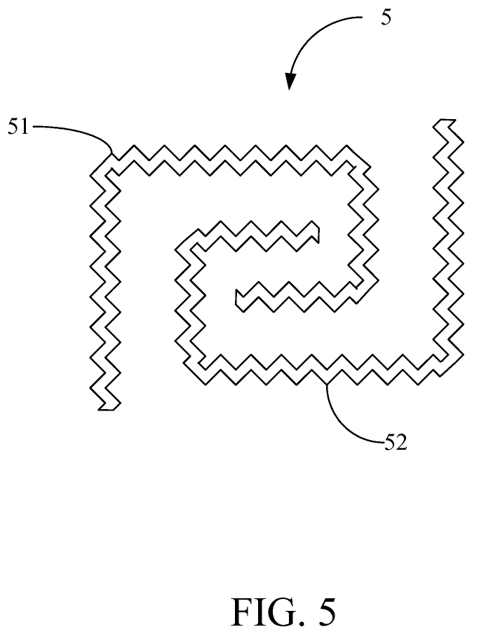

The main technical concept of the present invention can be applied to the symmetric structure as described in the first embodiment and various asymmetric structures. The third embodiment of the present invention, as shown in FIG. 4, is an asymmetric thin film transistor structure 4. The asymmetric thin film transistor structure 4 is substantially a combination of a plurality of the single asymmetric thin film transistor structures 3 of the second embodiment, so the length of the extending surface between a source 41 and a drain 42 is increased. The source 41 and the drain 42 also have a plurality of convex-concave surfaces corresponding to each other. The fourth embodiment of the present invention, as shown in FIG. 5, is an asymmetric thin film transistor structure 5, in which a source 51 and a drain 52 are whirled and the first main structure of the source 51 and the second main structure of the drain 52 have convex and concave contours that are mutually parallel, so that the length of the extending surface between the source 51 and the drain 52 is increased.

As described above in the embodiments, the thin film transistor of the present invention, whether symmetric or asymmetric, can substantially increase the length of the extending surface between the source and the drain, thereby increasing the ratio of the extending length to the distance and thus increasing the current charged value into the pixels by the thin film transistor. In addition, as the length of the extending surface between the source and the drain is increased without enlarging the volume of the source and the drain, the charging ability of the thin film transistor is improved without increasing the parasitic capacitor.

The above embodiments merely give the detailed technical contents of present invention and inventive features thereof, and are not to limit the covered range of the present invention. People skilled in this field may proceed with a variety of modifications and replacements based on the disclosures and suggestions of the invention as described without departing from the characteristics thereof. Nevertheless, although such modifications and replacements are not fully disclosed in the above descriptions, they have substantially been covered in the following claims as appended.

What is claimed is:

1. A thin film transistor structure, comprising:
a source, comprising a first portion, the first portion having a first edge; and
a drain, comprising a second portion, the second portion having a second edge;
wherein the first edge is toward the second portion, the second edge is toward the first portion, the first edge and the second edge have a plurality of convex-concave surfaces respectively, and the convex-concave surfaces of the first edge and the convex-concave surfaces of the second edge are substantially complementary.

2. The thin film transistor structure as claimed in claim 1, wherein the convex-concave surfaces are at least partially continuous.

3. The thin film transistor structure as claimed in claim 1, wherein the convex-concave surfaces comprise an angular shape having a sharp angle, and the sharp angle is about 60 to 120 degrees.

4. The thin film transistor structure as claimed in claim 1, wherein the convex-concave surfaces comprise a rectangle, an arc, a trapezoid or a combination thereof, the arc comprises a circular arc, and the circular arc has a central angle of about 60 to 120 degrees.

5. The thin film transistor structure as claimed in claim 1, wherein the first potion and the second portion appropriately define an extending length along the convex-concave surfaces, the first edge and the second edge define a distance therebetween, and the ratio of the extending length and the distance are substantially between 1 and 20.

6. The thin film transistor structure as claimed in claim 1, wherein the source comprises at least a male structure and the drain comprises at least a female structure corresponding to the male structure.

7. The thin film transistor structure as claimed in claim 1, wherein the first portion and the second portion are substantially parallel to each other.

8. The thin film transistor structure as claimed in claim 1, further comprising:
a gate, being insulated from the source and the drain; and
a channel layer, the channel layer having two ends substantially electrically connected to the source and the drain respectively.

9. A thin film transistor structure, comprising:
a source, comprising a first main structure and a first microstructure, the first microstructure being at least partially formed along the contour of the first main structure; and
a drain, comprising a second main structure and a second microstructure, the second microstructure being at least partially formed along the contour of the second main structure;
wherein the first microstructure is at least partially toward the drain, the second microstructure is at least partially toward the source, the first microstructure and the second microstructure have a plurality of convex-concave surfaces respectively, and the convex-concave surfaces of the first microstructure and the convex-concave surfaces of the second microstructure are corresponding to each other.

10. The thin film transistor structure as claimed in claim 9, wherein the convex-concave surfaces of the first microstructure and the convex-concave surfaces of the second microstructure are substantially complementary.

11. The thin film transistor structure as claimed in claim 9, wherein the convex-concave surfaces are at least partially continuous.

12. The thin film transistor structure as claimed in claim 9, wherein the convex-concave surfaces comprise an angular shape having a sharp angle, and the sharp angle is about 60 to 120 degrees.

13. The thin film transistor structure as claimed in claim 9, wherein the convex-concave surfaces comprise a rectangle, an arc, a trapezoid or a combination thereof, the arc comprises a circular arc, and the circular arc has a central angle about 60 to 120 degrees.

14. The thin film transistor structure as claimed in claim 9, wherein the first main structure and the second main structure define an extending length along the convex-concave surfaces, the first microstructure and the second microstructure define a distance therebetween, and the ratio of the extending length to the distance are substantially between 1 and 20.

15. The thin film transistor structure as claimed in claim 9, wherein the convex-concave surfaces at least comprise a concave and a convex, the concave of the first microstructure are corresponding to the convex of the second microstructure, and the convex of the first microstructure are corresponding to the concave of the second microstructure.

16. The thin film transistor structure as claimed in claim 9, wherein the first main structure of the source is a rectangle, the second main structure of the drain is in the shape of U, and the drain substantially surrounds the source.

17. The thin film transistor structure as claimed in claim 9, wherein the first main structure of the source and the second main structure of the drain are in the shape of whirl and substantially parallel to each other.

18. The thin film transistor structure as claimed in claim 9, further comprising:
a gate, being insulated from the source and the drain; and
a channel layer, the channel layer having two ends substantially electrically connected to the source and the drain respectively.
